(19) United States
(12) Patent Application Publication
(10) Pub. No.: US 2013/0221999 A1
(43) Pub. Date: Aug. 29, 2013

(54) TESTING SYSTEM AND METHOD

(71) Applicant: FANG TIAN, Shenzhen City (CN)

(72) Inventor: FANG TIAN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/481,884

(22) Filed: May 28, 2012

(30) Foreign Application Priority Data
Feb. 24, 2012 (CN) 201210043305.1

(51) Int. Cl. G01R 31/00

(52) U.S. Cl. 324/750.01

(57) ABSTRACT

A testing method implemented by a testing system connected to an electronic device includes testing whether the electronic device is successfully powered on in a powering on/off test according to pre-set test parameters; detecting if the electronic device is successfully powered on in the powering on/off test; generating a pause signal when the electronic device is successfully powered on; upon receiving the pause signal, preventing from entering into testing powering off of the electronic device, controlling to test whether certain components in the electronic device can successfully perform some functions; generating a continue signal to test powering off of the electronic device after testing the certain components performing some functions; and testing whether the electronic device is successfully powered off in the powering on/off test. The testing system is also provided.

### BACKGROUND

1. Technical Field

The present disclosure relates to testing systems and methods, and particularly, to a testing system and method for testing whether certain components in an electronic device can successfully perform some functions between powering on and off.

2. Description of Related Art

Current methods of testing whether an electronic device is successfully powered on/off perform predetermined number of testing to only test the ability of powering on/off of the computer. However, there is a need to test whether certain components in the computer can successfully perform some functions between powering on and off. For example, whether a CPU works under a predetermined power, whether each channel of the memory can work normally, and whether the mouse and keyboard can be identified between powering on and powering off in a powering on/off test.

### BRIEF DESCRIPTION OF THE DRAWINGS

Many aspects of the present embodiments can be better understood with reference to the drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a block diagram of an embodiment of a testing system, in accordance with the present disclosure.

FIG. 2 is a flowchart of an embodiment of testing method implemented by the testing system in FIG. 1, in accordance with the present disclosure.

### DETAILED DESCRIPTION

Embodiments of the present disclosure will be described with reference to the accompanying drawings.

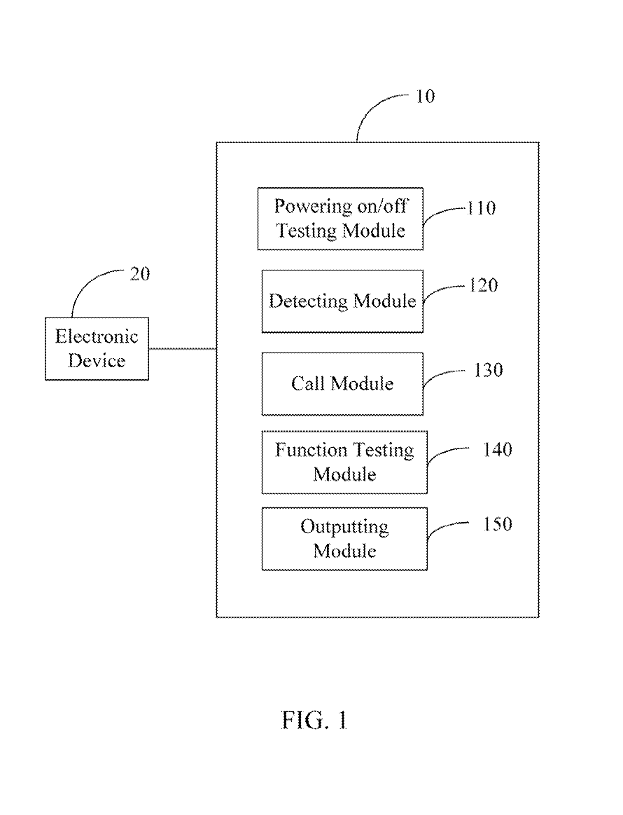

FIG. 1 is a block diagram of an embodiment of a testing system, in accordance with the present disclosure. The testing system 10 is connected to an electronic device 20, to test whether the electronic device 20 is successfully powered on/off and whether certain components in the electronic device 20 can successfully perform some functions between powering on and off. The testing system 10 can run on a computer or a single chip. The testing system 10 includes a powering on/off testing module 110, a detecting module 120, a call module 130, a function testing module 140, and an outputting module 150.

The powering on/off testing module 110 is used to set test parameters from a user after the testing system 10 is connected to the electronic device 20, test whether the electronic device 20 is successfully powered on/off in a powering on/off test according to pre-set test parameters and record a first test result. The test parameters include a number of testing whether the electronic device 20 is successfully powered on/off, and/or a delay time from being powered on to powered off. For example, the powering on/off testing module 110 can be set to test whether the electronic device 20 is successfully powered on/off for 500 times. The first test result indicates whether the electronic device 20 is successfully powered on/off. The method for test whether the electronic device 20 is successfully powered on/off can be referenced from existing technology.

The detecting module 120 is used to detect if the electronic device 20 is successfully powered on in the powering on/off test, generate a pause signal when the electronic device 20 is successfully powered on. In response to the pause signal, the powering on/off testing module 110 prevents the electronic device 20 from entering into test whether the electronic device is successfully powered off, and the call module 130 recalls the function testing module 140 to test whether certain components in the electronic device 20 can successfully perform some functions.

The function testing module 140 is used to test whether certain components in the electronic device 20 can successfully perform some functions, such as central processing unit (CPU), memory, mouse, and/or keyboard, and then record a second test result. The second test result indicates whether the CPU works under a predetermined power, whether each channel of the memory whether can work normally and whether the mouse and keyboard can be identified. Testing method of whether certain components in the electronic device 20 can successfully perform some functions can be referenced from existing technology.

The call module 130 is used to prevent the powering on/off testing module 110 from entering into testing powering off of the electronic device 20 upon receiving the pause signal from the detecting module 120, control the function testing module 140 to test whether certain components in the electronic device 20 can successfully perform some functions, and generate and send a continue signal to the powering on/off testing module 110 to test powering off of the electronic device 20 after the function testing module 140 has tested the certain components performing some functions.

The outputting module 150 is used to output the first test result and the second test result, such as printing out or display.

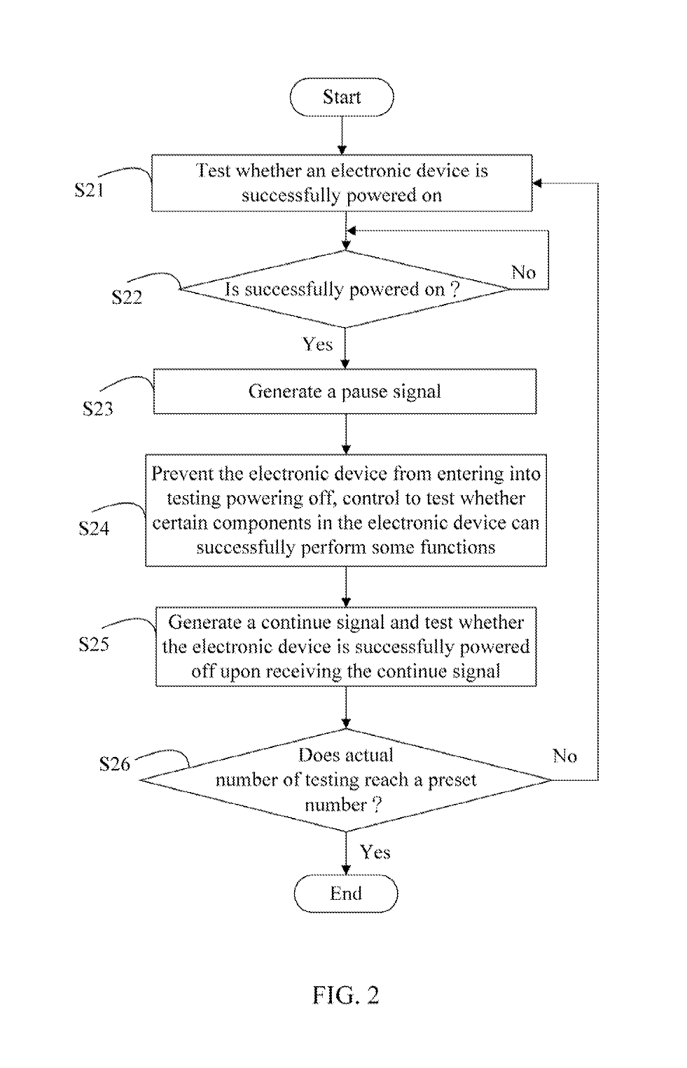

FIG. 2 is a flowchart of an embodiment of testing method implemented by the testing system in FIG. 1, in accordance with the present disclosure.

In step S21, the powering on/off testing module 110 tests whether the electronic device 20 is successfully powered on in a powering on/off test according to pre-set test parameters.

In step S22, the detecting module 120 detects if the electronic device 20 is successfully powered on in the powering on/off test. If yes, the procedure goes to S23, if no, the procedure repeats S22.

In step S23, the detecting module 120 generates a pause signal whether the electronic device 20 is successfully powered off.

In step S24, upon receiving the pause signal, the call module 150 prevents the powering on/off testing module 110 from entering into testing powering off of the electronic device 20, control the function testing module 140 to test whether certain components in the electronic device 20 can successfully perform some functions, such as CPU, memory, mouse, and/or keyboard, and then record the second test result.

In step S25, the call module 130 generates and sends a continue signal to the powering on/off testing module 110 after the function testing module 140 has tested the certain components performing some functions, the powering on/off testing module 110 tests whether the electronic device 20 is successfully powered off in the powering on/off test upon receiving the continue signal.

In step S26, the powering on/off testing module 110 determines if an actual number of testing whether the electronic device 20 is successfully powered on/off reaches to the preset number of testing whether the electronic device 20 is successfully powered on/off. If yes, the procedure goes to S27, if no, the procedure goes to S21.

Though above system and method, the testing system and method tests whether certain components in the electronic device 20 can successfully perform some functions between powering on and off, which is useful and convenient.

Although the features and elements of the present disclosure are described as embodiments in particular combinations, each feature or element can be used alone or in other various combinations within the principles of the present disclosure to the full extent indicated by the broad general meaning of the terms in which the appended claims are expressed.

What is claimed is:

1. A testing system for connected to an electronic device, the testing system comprising:
a powering on/off testing module, to test whether the electronic device is successfully powered on/off in a powering on/off test according to pre-set test parameters and record a first test result;
a detecting module, to detect if the electronic device is successfully powered on in the powering on/off test, generate a pause signal when the electronic device is successfully powered on;
a function testing module, to test whether certain components in the electronic device can successfully perform some function and record a second test result; and
a call module, to upon receiving the pause signal from the detecting module, to then prevent the powering on/off testing module from entering into testing powering off of the electronic device, control the function testing module to test whether certain components in the electronic device can successfully perform some functions, and generate and send a continue signal to the powering on/off testing module to test powering off of the electronic device after the function testing module has tested the certain components performing some functions.

2. The testing system of claim 1, wherein the testing system is run on a computer or a single chip.

3. The testing system of claim 1, wherein the powering on/off testing module is further used to set the test parameters from a user after the testing system is connected to the electronic device.

4. The testing system of claim 1, wherein the test parameters comprise a number of testing whether the electronic device is successfully powered on/off, and/or a delay time from powering on to powering off.

5. The testing system of claim 1, wherein the first test result indicates whether the electronic device is successfully powered on/off.

6. The testing system of claim 1, wherein the second test result indicates whether the CPU works under a predetermined power, whether each channel of the memory whether can work normally and whether the mouse and keyboard can be identified.

7. The testing system of claim 1, further comprising an outputting module to output the recorded first test result and second test result.

8. A testing method implemented by a testing system connected to an electronic device, the testing method comprising:
testing whether the electronic device is successfully powered on in a powering on/off test according to pre-set test parameters;
detecting if the electronic device is successfully powered on in the powering on/off test;
generating a pause signal when the electronic device is successfully powered on;
upon receiving the pause signal, preventing the electronic device from entering into testing powering off, controlling to test whether certain components in the electronic device can successfully perform some functions; and
generating a continue signal after testing the certain components performing some functions, and testing whether the electronic device is successfully powered off in the powering on/off test upon receiving the continue signal.

9. The testing method of claim 8, wherein the testing method is run on a computer or a single chip.

10. The testing method of claim 8, wherein the method further comprises setting the test parameters from a user after the testing system is connected to the electronic device.

11. The testing method of claim 8, wherein the test parameters comprise a number of testing whether the electronic device is successfully powered on/off, and/or a delay time from powering on to powering off.

12. The testing method of claim 8, wherein the first test result indicates whether the electronic device is successfully powered on/off.

13. The testing method of claim 8, wherein the second test result indicates whether the CPU works under a predetermined power, whether each channel of the memory whether can work normally and whether the mouse and keyboard can be identified.
